(19) United States
(12) Patent Application Publication
(10) Pub. No.: US 2009/0225621 A1
(43) Pub. Date: Sep. 10, 2009

(54) SPLIT DECODER STORAGE ARRAY AND METHODS OF FORMING THE SAME

(76) Inventor: Daniel R. Shepard, North Hampton, NH (US)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/398,659

(22) Filed: Mar. 5, 2009

Related U.S. Application Data
(60) Provisional application No. 61/068,174, filed on Mar. 5, 2008.

(51) Int. Cl. G11C 8/10; H01S 4/00; G11C 8/00

(52) U.S. Cl. 365/230.06; 29/592.1; 365/230.01

(57) ABSTRACT

A memory device includes a memory array comprising a plurality of generally parallel rows and a plurality of generally parallel columns intersecting the plurality of rows; a first address decoder circuit disposed on a first side of the memory array; and a second address decoder circuit disposed on a second side of the memory array different from the first side. At least two consecutive rows are connected to the first address decoder circuit and at least two other consecutive rows are connected to the second address decoder circuit.

### CROSS-REFERENCE TO RELATED APPLICATION

This application claims priority to and the benefit of U.S. Provisional Patent Application No. 61/068,174, filed Mar. 5, 2008. The entire disclosure of this application is incorporated by reference herein.

### TECHNICAL FIELD

In various embodiments, the present invention relates to information storage devices, and in particular to devices having decoder circuitry divided along at least two sides of an information storage array.

### BACKGROUND

Most non-volatile storage arrays feature memory cells arranged in lines, e.g., bit and/or word lines, each connected to a driver circuit. As device geometries shrink, these driver circuits must be packed very tightly to maintain the narrow pitch of the array lines. One solution, which enables the driver circuits to be fabricated at half the pitch of the array lines, places the driver circuits on two sides of the array, with alternate array lines exiting the array on opposite sides. For example, U.S. Pat. No. 7,054,219 to Petti et al. (“the '219 patent”), the entire disclosure of which is hereby incorporated by reference, discloses a simple alternating pattern for connecting drive transistors to memory array lines. However, packing density, while important, is not the only variable to consider when fabricating a memory array.

Another important consideration is the ability to successfully perform error correction on blocks of data stored in the memory array. U.S. Pat. No. 7,149,934 to Shepard (“the '934 patent”), the entire disclosure of which is hereby incorporated by reference, describes a method for improving the results of error-correcting codes (ECC) and algorithms by accessing the bits in the array such that fewer bits are accessed from any given array line than can be corrected by the ECC. In this way, if a common failure mechanism affecting multiple bits (such as a break in an array line or a short between two or more array lines) should occur, the number of bits lost to that fault will be limited. However, this method still requires connections between each array line and its driver circuitry. Clearly, there exists a need for a method of incorporating robust error correction into a memory array that maximizes packing density.

### SUMMARY

Embodiments of the present invention include memory-array storage devices having at least one split address decoder, where alternating groups of array lines (the groups including two or more lines) are connected to either the left-side or right-side decoder. Such configurations enable high packing density and efficient error correction. The decode logic is simplified while providing a more robust error-correctable access order—for any particular array (or portion thereof), the number of bad bits accessed after a short between two lines is reduced.

In an aspect, embodiments of the invention feature a memory device including a memory array including a plurality of generally parallel rows and a plurality of generally parallel columns intersecting the plurality of rows. A first address decoder circuit is disposed on a first side of the memory array, and a second address decoder circuit is disposed on a second side of the memory array different from the first side. At least two consecutive rows are connected to the first address decoder circuit and at least two other consecutive rows are connected to the second address decoder circuit.

One or more of the following features may be included. The first and second sides of the memory array may be opposed across the memory array. Alternating pairs of rows may be connected to the first address decoder circuit and to the second address decoder circuit. The memory device may include a third address decoder circuit disposed on a third side of the memory array different from the first and second sides, as well as a fourth address decoder circuit disposed on a fourth side of the memory array different from the first, second, and third sides. At least two consecutive columns may be connected to the third address decoder circuit and at least two other consecutive columns may be connected to the fourth address decoder circuit. The third and fourth sides of the memory array may be opposed across the memory array. Alternating pairs of columns may be connected to the third address decoder circuit and to the fourth address decoder circuit.

A driver device may be connected to each row and/or column. The driver device may include or consist essentially of a field-effect transistor. At least one row address line may be connected to both the first address decoder circuit and the second address decoder circuit. A storage element may be proximate an intersection between a row and a column, and may include or consist essentially of at least one of a fuse, an antifuse, or a chalcogenide material.

In another aspect, embodiments of the invention feature a method of forming a memory device. A memory array including a plurality of generally parallel rows and a plurality of generally parallel columns intersecting the plurality of rows is provided. A first address decoder circuit disposed on a first side of the memory array, as well as a second address decoder circuit disposed on a second side of the memory array different from the first side, are provided. At least two consecutive rows are connected to the first address decoder circuit, and at least two other consecutive rows are connected to the second address decoder circuit.

One or more of the following features may be included. The first and second sides of the memory array may be opposed across the memory array. Alternating pairs of rows may be connected to the first address decoder circuit and to the second address decoder circuit. A third address decoder circuit disposed on a third side of the memory array different from the first and second sides, as well as a fourth address decoder circuit disposed on a fourth side of the memory array different from the first, second, and third sides, may be provided. At least two consecutive columns may be connected to the third address decoder circuit and at least two other consecutive columns may be connected to the fourth address decoder circuit. The third and fourth sides of the memory array may be opposed across the memory array. Alternating pairs of columns may be connected to the third address decoder circuit and to the fourth address decoder circuit.

A driver device connected to each row and/or column may be provided. The driver device may include or consist essentially of a field-effect transistor. At least one row address line may be connected to both the first address decoder circuit and the second address decoder circuit. A storage element may be provided proximate an intersection between a row and a column, and may include or consist essentially of at least one of a fuse, an antifuse, or a chalcogenide material.

In a further aspect, embodiments of the invention feature a method of error correction including providing a memory device. The memory device includes or consists essentially of a memory array that itself includes or consists essentially of a plurality of generally parallel rows and a plurality of generally parallel columns intersecting the plurality of rows. A first row is accessed through a first address decoder circuit, and a second row is accessed through a second address decoder circuit different from the first address decoder circuit. The second row may be accessed immediately after accessing the first row, e.g., no other rows in the array may be accessed therebetween. At least one additional row is disposed between the first row and the second row.

These and other objects, along with advantages and features of the present invention herein disclosed, will become more apparent through reference to the following description, the accompanying drawings, and the claims. Furthermore, it is to be understood that the features of the various embodiments described herein are not mutually exclusive and may exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 is a schematic of a cross-point memory array circuit with single-sided decoding as found in the prior art;

FIGS. 2 and 3 are schematics of cross-point memory array circuits with split, dual-sided decoding as found in the prior art;

FIG. 4 is a plan view of a layout of one side of a split decoder as shown in the prior art;

FIG. 5 is a schematic of a cross-point memory array circuit with split, dual-sided decoding according to embodiments of the present invention; and

FIG. 6 is a plan view of a layout of one side of a split decoder according to embodiments of the present invention.

### DETAILED DESCRIPTION

FIG. 1 schematically depicts a cross-point memory array structure with individual word-line and bit-line decoders. Storage cells in the array (represented by circles) are present at the intersection of each row R0-R4 and each column C4-C0. The rows and columns are also commonly referred to as word lines and bit lines, respectively. One such exemplary array is described in U.S. Pat. No. 5,673,218 to Shepard, the entire disclosure of which is hereby incorporated by reference. In the array of FIG. 1, electrical power for reading or writing (at a voltage +V) is applied through a series of row drivers, each of which may consist of, e.g., a single FET, and to ground (GND) through a series of column drivers, each of which may consist of a single FET, as well as signal sense circuitry. Each storage cell includes or consists of, e.g., a diode having its anode connected to a row and a cathode connected to a column. Addressing a particular memory cell may be accomplished by applying +V to a given row and a path to GND activated on a given column. The state of the bit at the intersection of the selected row and the selected column is generally sensed as a current in the column driver.

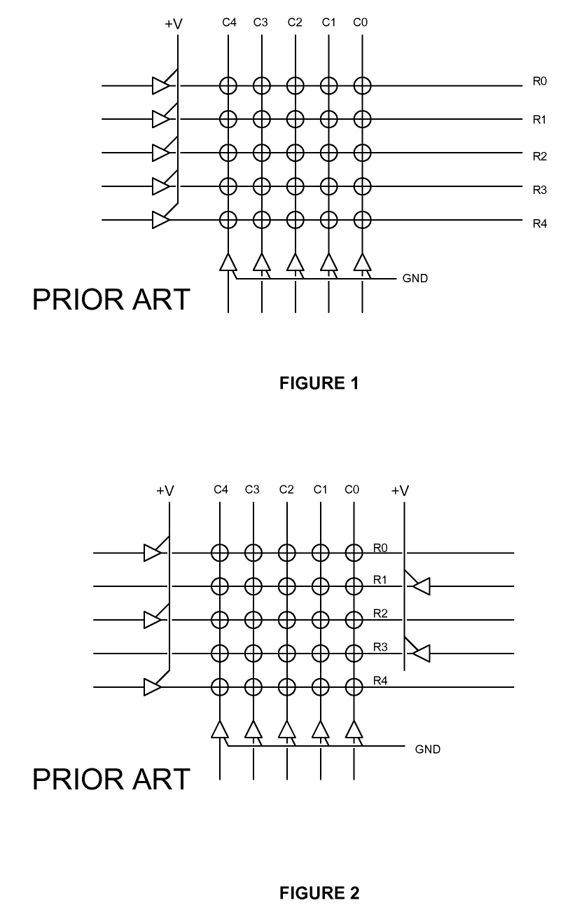

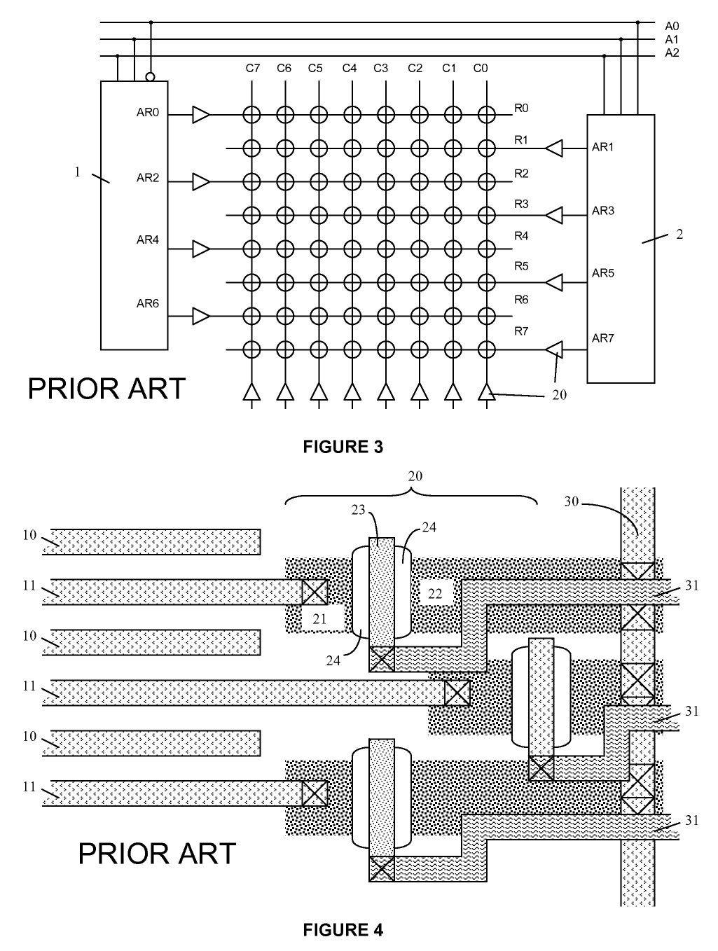

FIG. 2 schematically depicts a cross-point memory array structure with a split word-line decoder; each half of the decoder is positioned on an opposite side of the array. In accordance with the abovementioned '219 patent, the word lines connect to the left-side decoder and the right-side decoder in an alternating fashion. FIG. 3 depicts a more detailed version of the array of FIG. 2 in which address lines A0-A2 connect to the array and enable addressing of each memory bit. Specifically, a lowest-order address line A0 selects between the two array access sides, i.e., a low state on A0 selects the left-side decoder 1 and a high state on A0 selects the right-side decoder 2. Then, address lines A1 and A2 select one of four word lines (i.e., the four word lines connected to the selected decoder). When a standard ECC technique is implemented with the array of FIG. 4, each of the rows of the array will be selected in order (i.e., R0, R1, R2, . . . , R7). Thus, if the error correction approach of the '934 patent is utilized with the array of FIG. 3, a short between two word lines will actually increase the number of lost bits. For example, if R0 and R1 are shorted together, all the bits on these first two lines will be lost.

A possible solution to this bit-loss problem involves the connection of the highest-order address bit (here A2) to the decoder inputs that select between the decoders on either side of the array. However, two decoders are preferably operated in parallel with the reading or writing of data bits selected by the previously addressed location. In other words, once the first address is loaded and latched into the left-side decoder 1, the address lines become available to load and latch the subsequent address into the right-side decoder 2 (i.e., a separate decoder circuit) while the left side decoder 1 decodes the first address and outputs the selection, and the voltages on the selected word-line stabilize. If the addressing order is such that the same decoder is used to select consecutive word lines, this parallelism cannot be utilized and performance of the array is degraded. Hence, the selection between left-side decoder 1 and right-side decoder 2 is preferably done with the lowest order address bit (here A0).

FIG. 4 depicts a portion of a generalized integrated-circuit layout utilized with the approach of FIG. 3. In FIG. 4, the driver devices 20 disposed between and connecting the right-side decoder 2 and the even-numbered word lines 11 each include a single field-effect transistor (FET), e.g., an n-type metal oxide semiconductor (NMOS) FET or a p-type metal oxide semiconductor (PMOS) FET. Each driver device 20 may include a source region 21 and a drain region 22, separated by a gate 23. One or more spacers 24 insulate gate 23 from source region 21 and drain region 22. Each right-side output 31 (from the right-side decoder) connects to a gate 23, and a power bus 30 is common to all drain regions 22. It is understood that odd-numbered word lines 10 are connected to similar driver devices 20 and to the left-side decoder 1.

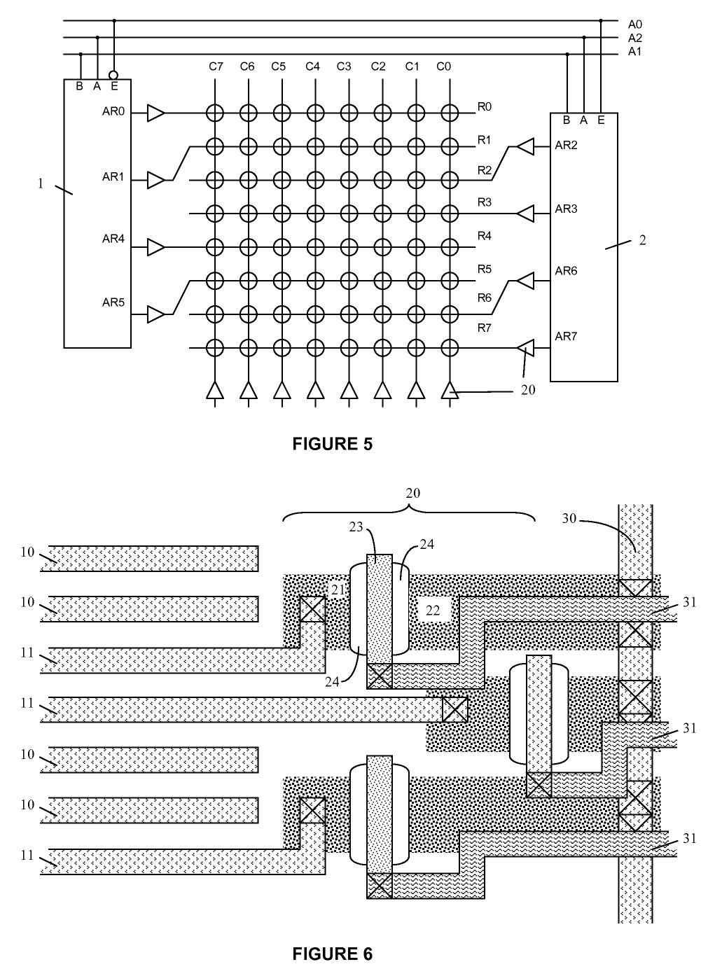

FIG. 5 schematically depicts an array with a split word-line decoder according to embodiments of the present invention. Here, the lowest-order address line A0 is preferably used to select between the left-side decoder 1 and the right-side decoder 2 in order to preserve the ability to parallelize the address loading into the decoders. However, when compared to the prior-art array of FIG. 3, the word-line connections are made in a manner enabling more efficient error correction. In embodiments of the present invention, the word lines R0-R7 alternately connect to the left-side and right-side decoders 1, 2 in groups of at least two lines, e.g., word lines R0 and R1 connect to the left-side decoder 1, word lines R2 and R3 connect to the right-side decoder 2, etc. In the specific embodiment embodied in FIG. 5, the word lines connections are alternated between left-side decoder 1 and right-side decoder 2 in a pair-wise fashion. Thus, one may address up to half of the word lines while alternating between the two decoders and utilize load-and-latch parallelism (as described above) without accessing two adjacent word lines consecutively. This functionality is enabled by the connection between the highest-order address bit (here A2) and the lowest-order address input (i.e., A) on both decoders. Specifically, accessing the first half of the array with sequential addresses (from the beginning of the address space) means that the array is addressed through all the even word lines. Then, accessing the second half of the array with sequential addresses (from the end of the first half of the array) will cause the remainder of the array to be addressed through all the odd word lines. Thus, in the event of a short between two adjacent lines, a sequential ECC process will result in fewer lost bits, as adjacent lines are never accessed consecutively. In the event of a short among more than two lines (e.g., in the event of large particulate contamination during a process such as photolithography), the grouping of lines into groups of more than two lines (e.g., three, four, or even five or more lines) will result in fewer lost bits during ECC, as multiple lines are “skipped” each time a new line is accessed.

FIG. 6 depicts a portion of a generalized integrated-circuit layout utilized in accordance with embodiments of the invention. In FIG. 6, groups (i.e., of more than two) of word lines 11 are connected to driver devices 20, which are themselves connected to the right-side decoder 2 (see also FIG. 5). Compared to the layout depicted in FIG. 4, layouts according to embodiments of the invention consume substantially the same amount of area while enabling more efficient error correction.

Embodiments of the invention may include a split decoder with pair-wise connections to bit lines, a split decoder with pair-wise connections to word lines, or both. Embodiments of the present invention will typically, although not necessarily, be built as integrated circuits. Variations will be apparent to those skilled in the art, including driver devices including or consisting essentially of components other than single FETs. Another embodiment of the invention includes a single word-line address decoder connected to word-line drivers, where the drivers are divided between two sides of the array and connect to the word lines in alternating pairs. Such an embodiment simplifies the addressing logic even without enabling the full benefit of parallelizing the address load and latch.

Embodiments of the present invention may include cross-point memory arrays (as described above) that may be tiles (or sub-arrays) in a larger device. The memory array may also be a portion of a three-dimensional memory array, which may be fabricated in accordance with U.S. Pat. No. 6,956,757 to Shepard, the entire disclosure of which is hereby incorporated by reference. The storage cells of the array may include at least one transistor, field emitter, diode, and/or any other device that conducts current asymmetrically at a given applied voltage. The storage elements may be fuses, antifuses, and/or devices including a phase-change material such as a chalcogenide (or other device capable of programmably exhibiting one of two or more resistance values). The storage element may even include a field-emitter programming element whose resistance and/or volume is changeable and programmable, e.g., a device described in U.S. patent application Ser. Nos. 11/707,739 or 12/339,696, the entire disclosures of which are hereby incorporated by reference. The storage cells and/or storage elements may be present at or near one or more intersections between a row and a column, and may even be present at all such intersections. In an embodiments, various intersections may even include different types of storage cells or elements.

It should be noted that the terms left-side, right-side, rows, columns, word lines, and bit lines are utilized interchangeably, and thus memory arrays in accordance with the present invention may be oriented arbitrarily. The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

1. A memory device comprising:
a memory array comprising a plurality of generally parallel rows and a plurality of generally parallel columns intersecting the plurality of rows;
a first address decoder circuit disposed on a first side of the memory array; and
a second address decoder circuit disposed on a second side of the memory array different from the first side,
wherein at least two consecutive rows are connected to the first address decoder circuit and at least two other consecutive rows are connected to the second address decoder circuit.

2. The memory device of claim 1, wherein the first side of the memory array and the second side of the memory array are opposed across the memory array.

3. The memory device of claim 1, wherein alternating pairs of rows are connected to the first address decoder circuit and to the second address decoder circuit.

4. The memory device of claim 1, further comprising:
a third address decoder circuit disposed on a third side of the memory array different from the first and second sides; and
a fourth address decoder circuit disposed on a fourth side of the memory array different from the first, second, and third sides,
wherein at least two consecutive columns are connected to the third address decoder circuit and at least two other consecutive columns are connected to the fourth address decoder circuit.

5. The memory device of claim 4, wherein the third side of the memory array and the fourth side of the memory array are opposed across the memory array.

6. The memory device of claim 4, wherein alternating pairs of columns are connected to the third address decoder circuit and to the fourth address decoder circuit.

7. The memory device of claim 1, further comprising a driver device connected to each row.

8. The memory device of claim 7, wherein each driver device consists essentially of a field-effect transistor.

9. The memory device of claim 1, further comprising a driver device connected to each column.

10. The memory device of claim 9, wherein each driver device consists essentially of a field-effect transistor.

11. The memory device of claim 1, further comprising at least one row address line connected to both the first address decoder circuit and the second address decoder circuit.

12. The memory device of claim 1, further comprising a storage element proximate an intersection between a row and a column, the storage element comprising at least one of a fuse, an antifuse, or a chalcogenide material.

13. A method of forming a memory device, the method comprising:
providing a memory array comprising a plurality of generally parallel rows and a plurality of generally parallel columns intersecting the plurality of rows;
providing a first address decoder circuit disposed on a first side of the memory array;
providing a second address decoder circuit disposed on a second side of the memory array different from the first side;
connecting at least two consecutive rows to the first address decoder circuit; and
connecting at least two other consecutive rows to the second address decoder circuit.

14. The method of claim 13, wherein the first side of the memory array and the second side of the memory array are opposed across the memory array.

15. The method of claim 13, wherein alternating pairs of rows are connected to the first address decoder circuit and to the second address decoder circuit.

16. The method of claim 13, further comprising:
providing a third address decoder circuit disposed on a third side of the memory array different from the first and second sides;
providing a fourth address decoder circuit disposed on a fourth side of the memory array different from the first, second, and third sides;
connecting at least two consecutive columns to the third address decoder circuit; and
connecting at least two other consecutive columns to the fourth address decoder circuit.

17. The method of claim 16, wherein the third side of the memory array and the fourth side of the memory array are opposed across the memory array.

18. The method of claim 16, wherein alternating pairs of columns are connected to the third address decoder circuit and to the fourth address decoder circuit.

19. The method of claim 13, further comprising providing a driver device connected to each row.

20. The method of claim 19, wherein each driver device consists essentially of a field-effect transistor.

21. The method of claim 13, further comprising providing a driver device connected to each column.

22. The method of claim 21, wherein each driver device consists essentially of a field-effect transistor.

23. The method of claim 13, further comprising providing at least one row address line connected to both the first address decoder circuit and the second address decoder circuit.

24. The method of claim 13, further comprising providing a storage element proximate an intersection between a row and a column, the storage element comprising at least one of a fuse, an antifuse, or a chalcogenide material.

25. A method of error correction, the method comprising:
providing a memory device comprising a memory array that itself comprises a plurality of generally parallel rows and a plurality of generally parallel columns intersecting the plurality of rows;
accessing a first row through a first address decoder circuit; and
immediately thereafter, accessing a second row through a second address decoder circuit different from the first address decoder circuit,
wherein at least one additional row is disposed between the first row and the second row.
